(19) United States
(12) Patent Application Publication
(10) Pub. No.: US 2026/0221901 A1
(43) Pub. Date: Jul. 30, 2026

(54) PIEZOELECTRIC ENERGY HARVESTER

(71) Applicant: NITTO DENKO CORPORATION, Osaka (JP)

(72) Inventors: Yiling ZHANG, Temecula, CA (US); Daisuke MATSUKUMA, La Jolla, CA (US)

(21) Appl. No.: 19/145,419

(22) PCT Filed: Jan. 5, 2024
(86) PCT No.: PCT/US2024/010489

§ 371 Date: Jul. 2, 2025

Related U.S. Application Data
(60) Provisional application No. 63/478,909, filed on Jan. 6, 2023.

(51) Int. Cl. H02N 2/18; B60C 23/04; H02N 2/00; H10N 30/045; H10N 30/092; H10N 30/85

(52) U.S. Cl. CPC H02N 2/186; B60C 23/0411; H02N 2/22; H10N 30/045; H10N 30/092; H10N 30/852

(57) ABSTRACT

Described herein is a piezoelectric composite energy harvester (100) comprising a piezoelectric element (102) and an elastic cover layer (110). The piezoelectric element comprises a first electrode (104), a second electrode (106), and a piezoelectric layer (108) comprising a cross-linked silicone elastomer matrix and piezoelectric particles dispersed within the cross-linked silicone elastomer matrix. The elastic cover layer (110) is arranged to cover an outer side of the second electrode (106). The piezoelectric composite energy harvester is configured to bend, expand, contract, rotate, tilt, and/or move in all spatial directions.

### CROSS-REFERENCE TO RELATED APPLICATIONS

This application claims priority to U.S. Provisional Application No. 63/478,909, filed Jan. 6, 2023, which is incorporated by reference in its entirety.

### BACKGROUND

Unless otherwise indicated in the present disclosure, the details described in the present disclosure are not prior art to the claims in the present application and are not admitted to be prior art by inclusion in this section.

The piezoelectric effect is the induction of an electric charge in response to an applied mechanical strain, which may be used to convert mechanical energy into electrical energy. As a result, piezoelectric materials have been widely used to scavenge energies from the environment and body movement to power personal electronics, nanodevices and wireless sensors, etc. To extend the application fields of piezoelectric materials, good mechanical flexibility is often considered to be desirable. However, bulk piezoelectric ceramics such as PZT have high piezoelectric coefficients but low flexibility, while piezoelectric polymers such as polyvinylidene fluoride (PVDF) have good flexibility but relatively low piezoelectric coefficients. PVDF has limitations in that it may have difficulties in conforming to three-dimensional curved surfaces due to lack of stretchability. In addition, PVDF based piezoelectric harvesters may easily detach or lift off from the attached surface by repeated deformation. This may be an especially difficult issue when the target surface is constantly flexing and flexing, for example upon the inside surface of a vehicle's inflatable tire. Piezocomposites employing polydimethylsiloxane (PDMS or silicone) may have large conformity and are tolerant to deformation, but power generated is significantly lower.

Therefore, there is a need for piezoelectric harvesters that improves flexibility without sacrificing power generation for non-planar substrates.

### SUMMARY

The embodiments of the disclosure solve these problems and generally relates to the layered architecture for a piezoelectric composite energy harvester that generates power in the context of a non-planar environment.

Some embodiments include a piezoelectric composite energy harvester comprising a piezoelectric element. In some embodiments, the piezoelectric element may comprise a first electrode, a second electrode, and a piezoelectric layer comprising a cross-linked silicone elastomer matrix and piezoelectric particles, having the piezoelectric particles dispersed within the cross-linked silicone elastomer matrix. In some embodiments, the first electrode and the second electrode are disposed on a first side of the piezoelectric layer and a second side of the piezoelectric layer, respectively. In some embodiments, the first electrode and the second electrode may comprise a conductive material and a silicone. In some embodiments, the conductive material may comprise a conductive particle. In some embodiments, the conductive particle may comprise carbon black, nickel nano strands, silver nanoparticles, graphene nanoplatelets, and/or graphene-oxide. In some embodiments, the piezoelectric composite energy harvester may be configured to bend, expand, contract, rotate, tilt, and/or move in all spatial directions due to an exposure to a mechanical stress.

In some embodiments, the piezoelectric energy harvester may comprise an elastic cover layer. In some embodiments, the elastic cover layer may be contiguous with the second electrode. In some embodiments, the elastic cover layer may be arranged so as to cover an outer side of the second electrode. In some embodiments, the elastic modulus of the elastic cover layer is less than the elastic modulus of the piezoelectric element. In some embodiments, the elastic cover layer may comprise silicone.

In some embodiments, the thickness ratio of the elastic cover layer to the piezoelectric element is about 0.01 or more. In some embodiments, the thickness ratio of the elastic cover layer to the piezoelectric element is greater than about 0.01 and less than about 2. In some embodiments, the piezoelectric composite energy harvester has a tensile stress at 20% elongation of about 1.5 to about 4 MPa. In some embodiments, the piezoelectric composite energy harvester has a tensile stress at 35% elongation of about 1.5 to about 4 MPa. In some embodiments, the piezoelectric composite energy harvester has a tensile stress at 40% elongation of about 1.5 to about 4 MPa. In some embodiments, the piezoelectric composite energy harvester has a tensile stress at 45% elongation of about 2 to about 4.5 MPa. In some embodiments, the piezoelectric composite energy harvester has a tensile stress at 50% elongation of about 2 to about 4.5 MPa. In some embodiments, the piezoelectric layer has a thickness between about 5 μm to about 500 μm.

In some embodiments, the cross-linked elastomer may be formed from a reactive silicone oligomer that has a hardness of 5-90 Shore A. In some embodiments, the fraction of the reactive functional units in the reactive elastomer may be 5 mol % or above. In some embodiments, the elastomeric matrix may comprise a doped polyalkylsiloxane matrix, and piezoelectric particles, the piezoelectric particles dispersed within the polyalkylsiloxane matrix. In some embodiments, the elastomeric matrix may comprise a reactive oligomer having reactive functional groups selected from hydroxyl, vinyl, alkoxy and hydride. In some embodiments, the dopant may be platinum (Pt). In some embodiments, the polyalkylsiloxane may comprise polydimethylsiloxane. In some embodiments, the volume fraction of the piezoelectric particles in the piezoelectric layer may be 35-65%. In some embodiments, the cross-linked elastomer may comprise a volume fraction of 65% to 35% silicone. In some embodiments, the elastic electrodes may comprise carbon as a conductive element.

In some embodiments, a tire comprises the piezoelectric composite energy harvester described above.

In some embodiments, a method for preparing a piezoelectric composite harvesting composite comprises providing a silicone oligomer that after curing has a hardness of about 5 to about 90 Shore A; providing a mixture comprising piezoelectric particles dispersed within the silicone oligomer; casting the mixture to form a composite sheet; curing the composite sheet; polarizing the piezoelectric particles within the composite sheet; producing a first electrode from a conductive material, comprising forming the conductive material onto a first side of the composite sheet; producing a second electrode from a conductive material, comprising forming the conductive material onto a second side of the composite sheet; and producing an elastic cover layer from silicone, comprising forming the silicone onto the first electrode or the second electrode.

In some embodiments, the step of producing the first electrode and second electrode may comprise forming the conductive material by a printing method, a casting method, and/or a coating method. In some embodiments, the printing method may comprise screen printing. In some embodiments, the step of producing the elastic cover layer may comprise forming the conductive material by a printing method, a casting method, and/or a coating method. In some embodiments, the printing method may comprise screen printing.

These and other embodiments are described in greater detail below.

### BRIEF DESCRIPTION OF THE DRAWINGS

FIG. 1 is a drawing depicting an embodiment of a piezoelectric energy harvester.

FIG. 2 is a schematic depicting a sensor module that may be included in an embodiment of a piezoelectric energy harvester.

FIG. 3 is a schematic of an example energy generating circuit that may be included in an embodiment as described herein.

FIG. 4 is a graph illustrating the tensile stress of an embodiment of a piezoelectric energy harvester.

FIG. 5 is a graph illustrating the tensile stress of an embodiment of a piezoelectric energy harvester.

FIG. 6 is a graph illustrating the tensile stress of an embodiment of a piezoelectric energy harvester.

FIG. 7 is a graph illustrating the tensile stress of an embodiment of a piezoelectric energy harvester.

FIG. 8 is a graph illustrating the tensile stress of an embodiment of a piezoelectric energy harvester.

FIG. 9 is a graph illustrating the piezoelectricity energy generation of an embodiment of a piezoelectric energy harvester.

### DETAILED DESCRIPTION

The present disclosure relates to a piezoelectric composite energy harvester. For purposes of promoting an understanding of the present disclosure, reference will now be made to the following embodiments and specific language will be used to describe the same. It will nevertheless be understood that no limitation of the scope of the disclosure is thereby intended, such alterations and further modifications in the described subject matter, and such further applications of the disclosed principles as described herein being contemplated as would normally occur to one skilled in the art to which the disclosure relates.

In some applications, an elastic protective layer is implemented in piezoelectric sensors to improve sensitivity. However, an elastic protective layer disposed on the front and back of the piezoelectric sensor degrades the function of the piezoelectric sensor. When the thickness of the elastic protective layer is less than two times the piezoelectric layer, the flexibility of the piezoelectric sensor is reduced, and when the thickness of the elastic protective layer is greater than ten times the piezoelectric layer, the sensitivity of the sensor is impaired. Furthermore, disposing an elastic protective layer between a piezoelectric energy harvester and a substrate, e.g., a non-planar surface, will degrade the ability of the piezoelectric energy harvester to generate power efficiently. In other applications, the protective layer reduces the exposure of the piezoelectric sensor to mechanical stress, thus reducing power generation.

The present disclosure generally relates to piezoelectric power generating systems, which may comprise an elastic protective cover layer to improve flexibility without sacrificing piezoelectricity, to enable sufficient power generation and sufficient toughness to increase durability under conditions consistent with the use inside of a vehicular tire. In the present disclosure, a piezoelectric energy harvester is described.

As shown in FIG. 1, a piezoelectric energy harvester, such as piezoelectric energy harvester 100, may include a piezoelectric element, such as piezoelectric element 102, and an elastic cover layer, such as cover layer 110. In some embodiments, the piezoelectric energy harvester relies on mechanical stress, e.g., simple rotation of a tire, such as tire, and/or inherent vibrations from the tire, and converts this mechanical energy into electrical energy. In some embodiments, the piezoelectric energy harvester is flexible and may conform to a non-flat surface. In some embodiments, the piezoelectric energy harvester may conform to a flat surface.

In some embodiments, the piezoelectric element may comprise a first electrode, such as electrode 104, a second electrode, such as electrode 106, and a piezoelectric layer, such as piezoelectric layer 108. In some embodiments, the first electrode may be disposed on a first side of the piezoelectric layer and the second electrode may be disposed on a second side of the piezoelectric layer.

In some embodiments, the piezoelectric layer may comprise an elastomeric matrix and piezoelectric particles. In some embodiments, the piezoelectric particles may be dispersed within the elastomeric matrix. In some embodiments, the elastomeric matrix may comprise a reactive oligomer and the piezoelectric particles. In some embodiments, the elastomeric matrix may comprise cross-linked silicone. In some embodiments, the piezoelectric particles may be polarized (alignment of the piezoelectric particles' dipole moment).

In some embodiments, each of the first electrode and the second electrode may comprise a flexible material or elastomeric substrate. In some embodiments, the flexible material may comprise a silicone or the like and a conductive material. When the piezoelectric energy harvester is used in conjunction with a tire, silicone is softer than the tire, is very flexible, and does not restrict the capturing the mechanical stress or vibrations from the tire. Some non-limiting examples of silicone that may be used in the first electrode and the second electrode include LS-8941 (NuSil Technology, CA) or Sylgard182 (Dow Chemical, MI). In some embodiments, the conductive material may comprise nanoparticles, such as carbon black, nickel nano strands, silver nanoparticles, graphene nanoplatelets, graphene-oxide, or the like. The conductive particles in the first electrode and the second electrode may be distributed uniformly throughout the respective flexible material or elastomeric substrate, and/or may be arranged thereon or therein in a hatched or mesh pattern or structure.

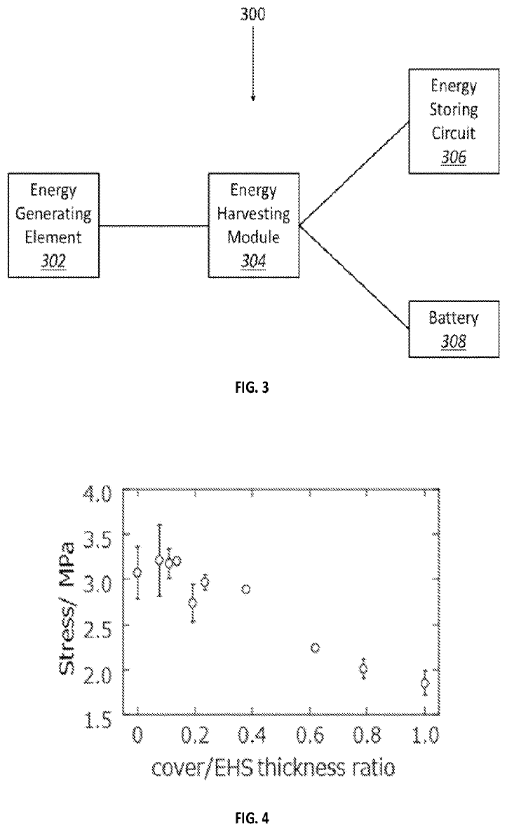

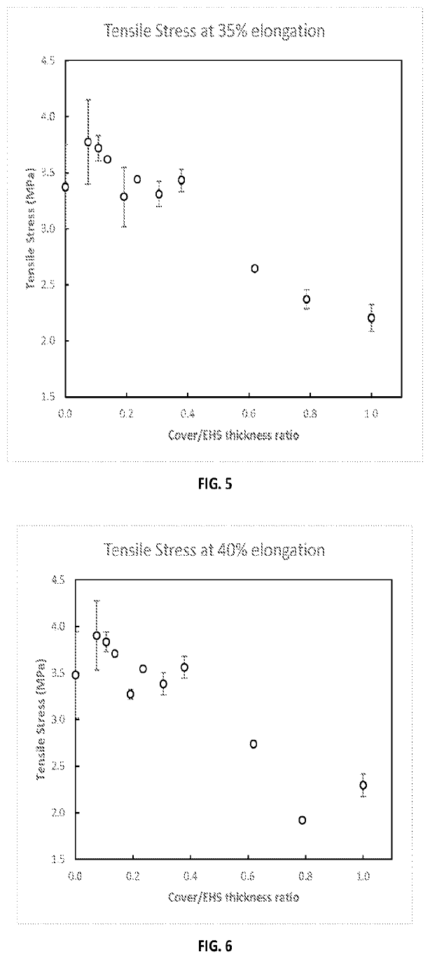

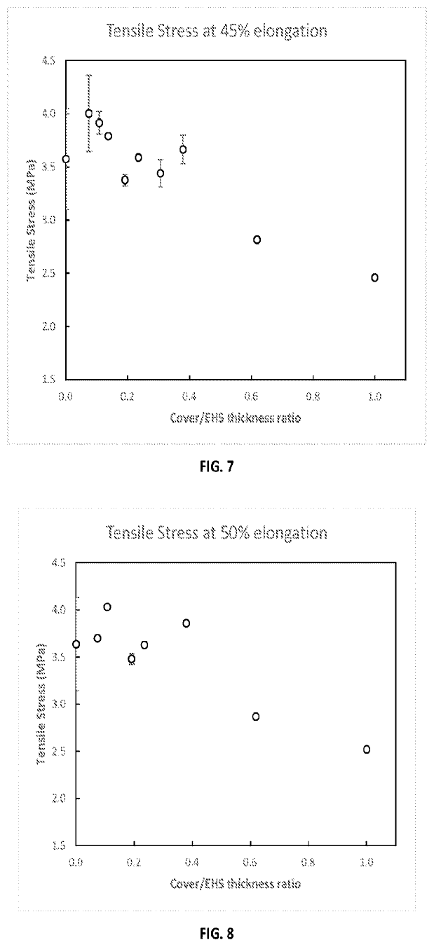

FIGS. 4-8 are graphs showing the effect of the elastic cover layer on the tensile stress of the piezoelectric energy harvester. In general, the graphs show the unexpected result of an improvement on the tensile stress for the piezoelectric energy harvester as described herein. In some embodiments, the piezoelectric energy harvester may have a device tensile stress at 20% elongation of about 0.5 MPa to about 5 MPa, about 1.5-4 MPa, about 0.5-1 MPa, about 1.5-2 MPa, about 2-2.5 MPa, about 2.5-3 MPa, about 3-3.5 MPa, about 3.5-4 MPa, about 4-4.5 MPa, about 4.5-5 MPa, or about 0.5 MPa, about 1 MPa, about 1.5 MPa, about 2 MPa, about 2.5 MPa, about 3 MPa, about 3.5 MPa, about 4 MPa, about 4.5 MPa, about 5 MPa, or any tensile stress at 20% elongation in a range bounded by any of these values.

In some embodiments, the piezoelectric energy harvester may have a device tensile stress at 35% elongation about 0.5 MPa to about 5 MPa, about 1.5-4 MPa, about 0.5-1 MPa, about 1.5-2 MPa, about 2-2.5 MPa, about 2.5-3 MPa, about 3-3.5 MPa, about 3.5-4 MPa, about 4-4.5 MPa, about 4.5-5 MPa, or about 0.5 MPa, about 1 MPa, about 1.5 MPa, about 2 MPa, about 2.5 MPa, about 3 MPa, about 3.5 MPa, about 4 MPa, about 4.5 MPa, about 5 MPa, or any tensile stress at 35% elongation in a range bounded by any of these values.

In some embodiments, piezoelectric energy harvester may have a device a tensile stress at 40% elongation of about 0.5 MPa to about 5 MPa, about 1.5-4 MPa, about 0.5-1 MPa, about 1.5-2 MPa, about 2-2.5 MPa, about 2.5-3 MPa, about 3-3.5 MPa, about 3.5-4 MPa, about 4-4.5 MPa, about 4.5-5 MPa, or about 0.5 MPa, about 1 MPa, about 1.5 MPa, about 2 MPa, about 2.5 MPa, about 3 MPa, about 3.5 MPa, about 4 MPa, about 4.5 MPa, about 5 MPa, or any tensile stress at 40% elongation in a range bounded by any of these values.

In some embodiments, piezoelectric energy harvester may have a device tensile stress at 45% elongation of about 0.5 MPa to about 6 MPa, about 1.5-4 MPa, about 0.5-1 MPa, about 1.5-2 MPa, about 2-2.5 MPa, about 2.5-3 MPa, about 3-3.5 MPa, about 3.5-4 MPa, about 4-4.5 MPa, about 4.5-5 MPa, about 5-5.5 MPa, about 5.5-6 MPa, or about 0.5 MPa, about 1 MPa, about 1.5 MPa, about 2 MPa, about 2.5 MPa, about 3 MPa, about 3.5 MPa, about 4 MPa, about 4.5 MPa, about 5 MPa, about 5.5 MPa, about 6 MPa, or any tensile stress at 45% elongation in a range bounded by any of these values. In some embodiments, piezoelectric energy harvester may have a device tensile stress at 50% elongation of about 0.5 MPa to about 6 MPa, about 1.5-4 MPa, about 0.5-1 MPa, about 1.5-2 MPa, about 2-2.5 MPa, about 2.5-3 MPa, about 3-3.5 MPa, about 3.5-4 MPa, about 4-4.5 MPa, about 4.5-5 MPa, about 5-5.5 MPa, about 5.5-6 MPa, or about 0.5 MPa, about 1 MPa, about 1.5 MPa, about 2 MPa, about 2.5 MPa, about 3 MPa, about 3.5 MPa, about 4 MPa, about 4.5 MPa, about 5 MPa, about 5.5 MPa, about 6 MPa, or any tensile stress at 50% elongation in a range bounded by any of these values.

In some embodiments, the silicone utilized to form the cross-linked elastomeric matrix, may have a hardness between the range of about 5 to about 90, as measured using the Shore hardness scale, type A (hereinafter referred to as Shore A). In some examples, the silicone used to form the cross-linked elastomeric matrix may comprise about 75% silicone, about 80% silicone, about 85% silicone, about 90% silicone, about 95% silicone, about 99% silicone, about 99.5% silicone, and/or about 99.9% silicone. In some embodiments, the silicone may be essentially pure silicone. Some non-limiting examples of silicone that may be used in the piezoelectric layer include LS-8941 (NuSil Technology, CA) or Sylgard182 (Dow Chemical, MI). It is believed that the specific silicone polymer, dopant, and/or crosslinker may contribute to a balancing of the hardness and flexibility and amount of power generation by the piezoelectric functionality of the piezoelectric material. Any suitable means to determine hardness may be utilized, e.g., ASTM D2240 standard, type A (hardened steel rod 1.1 mm-1.4 mm diameter with a truncated 35° cone, 0.79 mm diameter, with an applied mass (kg) of about 0.822 kg with a resulting force of about 8.064 Newtons (N). Any suitable means to determine material tensile strength may be employed, e.g., a tensile tester utilizing 5 mm/minute stroke speed.

Some embodiments include a piezoelectric layer comprising a cross-linked elastomer matrix. In some embodiments, the cross-linked elastomer matrix may comprise a silicone elastomer. In other embodiments, the silicone elastomer may comprise a polyalkylsiloxane. In some embodiments, the polyalkylsiloxane may comprise polydimethylsiloxane (PDMS). The type of cross-linking reaction of silicone is not limited to noble metal catalyzed and may include all other types of cross-linking reactions of silicone. In some embodiments, the polyalkylsiloxane may be doped with a noble metal. In some embodiments, the dopant may comprise Ag, Au, Pd, Ni, Pt, or any combination thereof. It is believed that Pt may catalyze the cross-linking reaction. In some embodiments, the noble metal may be platinum (Pt). In some embodiments, the PDMS elastomer may be doped with between 0.001 wt % to about 5 wt %, about 0.001-0.05 wt %, about 0.05-0.1 wt %, about 0.1-0.5 wt %, about 0.5-1 wt %, about 1-1.5 wt %, about 1.5-2 wt %, about 2-2.5 wt %, about 2.5-3 wt %, about 3-3.5 wt %, about 3.5-4 wt %, about 4-4.5 wt %, about 4.5-5 wt % noble metal, e.g., Pt, or any wt % in a range bounded by any of these values. It is believed that the doping of the silicone elastomer may contribute to the hardening of the elastomer so as to contribute to attaining a hardness level of 5-90 Shore A. In some embodiments, the presence of the dopant may affect metal (e.g., those mentioned above) catalyzed crosslinking.

In some embodiments, the cross-linked elastomer matrix may comprise a reactive silicone oligomer. In some embodiments, the reactive oligomer may comprise a reactive functionalized silicone monomer. In some embodiments, the reactive functionalized silicone monomer may comprise a reactive hydrogen group (silicone hydride), a reactive vinyl group, a reactive hydroxyl group, or a reactive alkoxy group. In some embodiments, the reactive elastomer may comprise silicone hydride (the silicone reactive functional group) and/or a poly-silicone vinyl (another silicone reactive functional group). In some embodiments, the fraction of reactive functional units in the reactive elastomer, meaning the ratio of the number of reactive monomer units to the total number of monomer units may be 5 mol % (e.g., one silicone monomer containing silicone hydride combined with 19 silicone monomers that are not reactive has a fraction of reactive function units of 5 mol %) or above. In some embodiments, the fraction of reactive functional units in the reactive elastomer may be 6% or above. In some embodiments, the fraction of reactive functional units in the reactive elastomer may be 7.5 mol % or above.

In some embodiments, the piezoelectric energy harvester may comprise piezoelectric particles dispersed or disposed within the cross-linked silicone elastomer matrix. In some embodiments, the volume fraction of the piezoelectric particles in the piezoelectric layer may be about 35% to about 65%. In some embodiments, a volume fraction of the piezoelectric particles in the piezoelectric layer that is about 40% to about 65% may provide improved power generation. In some embodiments, a volume fraction of the piezoelectric particles in the piezoelectric layer that is about 40% to about 55% may provide improved toughness. In some embodiments, the first elastic electrode and/or the second elastic electrode may comprise carbon as a conductive filler element. The conductive fillers may be dispersed within the elastomer matrix. A conductive filler is a compound which, introduced into a medium, in the presence of an electric current, allows an electric current to occur in the medium. The conductive filler may be a graphitized or partially graphitized carbon black, also known as conductive blacks. These conductive blacks may be, for example, that sold by Timcal under the trade name “Ensaco 350G”, with a specific surface (BET, measured according to Standard ASTM D3037) of 770 m²/g, or “Ensaco 260G”, with a specific surface of 70 m²/g. In some embodiments, the conductive filler may be an electro-conductive or graphitized carbon black with a specific surface (BET, measured by Standard ASTM D3037) of greater than 65 m²/g, of greater than 100 m²/g, and/or of greater than 500 m²/g. In some embodiments, the amount of conductive filler in the elastomer matrix composition may be within a range extending from about 35% to about 65% by volume. Suitable examples for conductive blacks include, but are not limited to, “Ensaco 260 G” from Timcal, or the conductive carbon black “Ensaco 350 G” from Timcal. The size of the conductive fillers advantageously varies from about 50 nm (nanometers) to about 500 μm (microns or micrometers). In some embodiments, the piezoelectric materials may have their dipole moments aligned by an external electric field. In some embodiments, the volume fraction of the piezoelectric particles may be from about 40% to about 65%.

In some embodiments, the piezoelectric energy harvester may comprise an elastic cover layer, such as cover layer 110 as shown in FIG. 1. In some embodiments, the elastic cover layer may be contiguous with the second electrode. In some embodiments, the elastic cover layer may be contiguous with the first electrode. In some embodiments, the elastic cover layer is arranged so as to cover an outer side of the piezoelectric element. In some embodiments, the elastic cover layer is arranged so as to cover an outer side of the second electrode. In some embodiments, the outer side of the piezoelectric element may comprise the outer top surface of the second electrode. In some embodiments, the outer side of the piezoelectric element may comprise the outer top surface of the first electrode. In some embodiments, the elastic cover layer partially covers the outer side of the piezoelectric element. In some embodiments, the elastic cover layer covers about 70% to about 100%, about 100%, about 99.999%, about 99.99%, about 99.9%, about 99%, about 98%, about 97%, about 96%, about 95%, about 90%, about 85%, about 80%, about 75%, about 70%, or any percentage in a range bounded by any of these values, of the outer side of the piezoelectric element. In some embodiments, the elastic cover layer does not extend down the sides of the piezoelectric composite energy harvester. In some embodiments, the elastic cover layer does not contact the substrate or the tire.

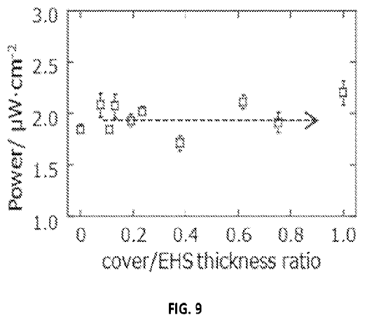

It is believed that covering or partially covering the outer top side of the piezoelectric element with the elastic cover layer, and not encapsulating or insulating the piezoelectric element, increases the flexibility and durability without limiting exposure of the piezoelectric element to mechanical stress, thus improving flexibility without sacrificing piezoelectric energy generation. For example, FIG. 9 is a graph showing the effect of the elastic cover layer on the piezoelectric element. In general, the graph shows the unexpected result of the piezoelectric energy harvester maintaining piezoelectric energy generation as the thickness of the elastic cover layer increases.

In some embodiments, the elastic cover layer may comprise a silicone. In some embodiments, the silicone used to form the elastic cover layer may comprise about 75% silicone, about 80% silicone, about 85% silicone, about 90% silicone, about 95% silicone, about 99% silicone, about 99.5% silicone, and/or about 99.9% silicone. In some embodiments, the silicone may be essentially pure silicone. Any suitable silicone may be used in the elastic cover layer and may include, but are not limited to, LS-8941 (NuSil Technology, CA), R-2188 (NuSil Technology, CA), or Sylgard182 (Dow Chemical, MI).

In some embodiments, the elastic modulus of the elastic cover layer is less than the elastic modulus of the piezoelectric element. In some embodiments, the elastic modulus of the elastic cover layer is less than the elastic modulus of the piezoelectric layer. In some embodiments, the elastic cover layer has a tensile stress at 1% elongation of about 0.01 to about 5 MPa. In some embodiments, the piezoelectric element has a tensile stress at 1% elongation of about 0.5 to about 5 MPa.

In some embodiments, the piezoelectric layer has a thickness between about 5 μm to about 500 μm, about 5-50 μm, about 50-100 μm, about 100-150 μm, about 150-200 μm, about 200-250 μm, about 250-300 μm, about 300-350 μm, about 300-450 μm, about 350-400 μm, about 400-450 μm, about 450-500 μm, or any thickness in a range bounded by any of these values.

In some embodiments, the piezoelectric energy harvester has a thickness between about 5 μm to about 5 mm, about 5 μm-50 μm, about 50-100 μm, about 100-150 μm, about 150-200 μm, about 200-250 μm, about 250-300 μm, about 300-350 μm, about 300-450 μm, about 350-400 μm, about 400-450 μm, about 450-500 μm, about 500 μm to about 1 mm, about 1-2 mm, about 2-3 mm, about 3-4 mm, about 4-5 mm, or any thickness in a range bounded by any of these values.

In some embodiments, the piezoelectric energy harvester may comprise a mounting surface. The mounting surface may be configured to be attached to a surface of the tire or other object or substrate. Alternatively, or additionally, the mounting surface may include an adhesive disposed thereon to adhere the piezoelectric energy harvester to a desired position within a tire (or other substrate) cavity, such as cavity 120 (as shown in FIG. 1), or exterior of an inner tube. The adhesive may comprise a thermoplastic adhesive or any other suitable adhesive.

In some embodiments, the piezoelectric energy harvester may be exposed to mechanical stress or multi-directional forces, e.g., a roll (z-axis), a pitch (y-axis) and/or a yaw (x-axis) forces. In some embodiments, the piezoelectric energy harvester is configured to bend, expand, contract, rotate, tilt, and/or move in all spatial directions due to an exposure to the mechanical stress. In some embodiments, the piezoelectric element is configured to bend, expand, contract, rotate, tilt, and/or move in all spatial directions due to an exposure to the mechanical stress. In some embodiments, the piezoelectric element is configured to be able to bend, expand, contract, rotate, tilt, and/or move in all spatial directions because the elastic cover layer only covers the outer side of the piezoelectric element and does not extend lower to the tire (or other substrate). It is believed that this configuration increases exposure of the piezoelectric element to a mechanical stress, because only the outer side of the piezoelectric element is covered or partially covered by the elastic cover layer, thus increasing piezoelectric energy generation while achieving greater flexibility.

In some embodiments, a vehicle (automobile, truck, tractor, etc.) tire may comprise a piezoelectric energy harvester described above. In some embodiments, the piezoelectric energy harvester may comprise a plurality of piezoelectric elements electively positioned in desired tire locations. In some embodiments, the piezoelectric energy harvester may be disposed upon a tread portion, a shoulder portion, and/or a sidewall portion of the tire. In some embodiments, the tire may be a tubeless tire, having a tire carcass with an inner surface, the tire forming an airtight seal with a wheel to define a reservoir for receipt of a gas, generally air, therein. The tire carcass may have a tire bead which interacts with the wheel to form the airtight seal. In some embodiments, the tire is used with an inner tube disposed within the reservoir to hold a gas, such as air, in which case the tire need not form an airtight seal with the wheel. The tire carcass may include a tread portion, a shoulder portion, and a sidewall portion.

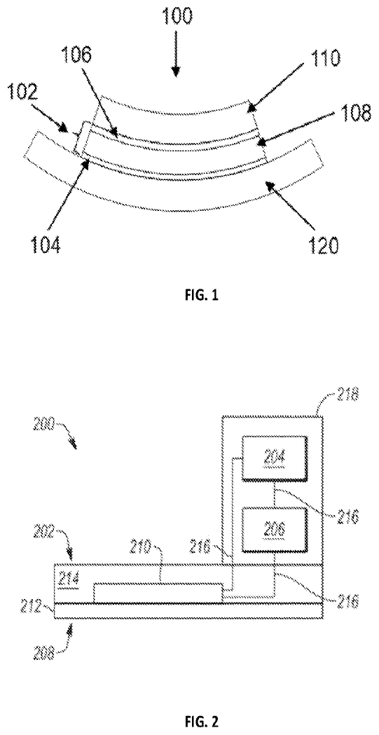

The piezoelectric energy harvester described herein is useful in coordination with capacitive tire sensors described in Patent Cooperation Treaty patent application (WO 2021/0168286, filled Feb. 19, 2021, publication date Aug. 26, 2021), which is incorporated by reference herein for its discussion of tire sensors and piezoelectric generators. As illustrated in FIG. 2, a sensor module, such as sensor module 200, may generally include a detector patch, such as detector patch 202, an electronics unit, such as electronics unit 204, and optionally an electric power source, such as electric power source 206. In some embodiments, the piezoelectric energy harvester 100 of FIG. 1 is suitable as the electric power source. In some examples, the piezoelectric harvester may comprise the electronics unit connected to the detector patch and the electric power source. In some embodiments, the electric power source may include the piezoelectric energy harvester system described herein.

The detector patch may include a mounting surface, such as mounting surface 208, and one or more sensor regions, such as sensor region 210. The mounting surface may be configured to be attached to a surface of the tire or other object and/or may include a lower or bottom surface of the detector patch. Alternatively, or additionally, the mounting surface may include an adhesive, such as adhesive 212, disposed thereon to adhere the detector patch to a desired position within a tire cavity of the tire or exterior of an inner tube. The adhesive may include a thermoplastic adhesive or any other suitable adhesive. The sensor region may generally include a capacitor. In some embodiments, the capacitor and/or the sensor region may be flexible, extensible, distensible, deformable, layered, and/or lamellar. Alternatively, or additionally, the sensor region may be at least partially covered, bound, and/or surrounded by one or more protective layers, such as protective layer 214, as part of the detector patch. The protective layers may include an elastomeric material such as silicone or the like. The electric power source may include a battery, an energy generating circuit, an energy harvesting system (EHS) module, a dielectric elastomer generating material, a piezoelectric harvester as described herein, and/or a receiver coil and circuitry of an inductive charging unit. The electronics unit may be in electrical communication with each of the detector patch and the power source via one or more corresponding electrical connectors, such as connectors 216. Alternatively, or additionally, the electronics unit and the electric power source may be mechanically coupled together by epoxy resin and/or may be disposed within a housing or encapsulant, such as encapsulant, that is mechanically coupled to the detector patch.

In some embodiments, a capacitive tire sensor may comprise an energy generating circuit and or element. As shown in FIG. 3, the energy generating circuit, such as energy generating circuit 300, may include an energy generating element, such as energy generating element 302, an EHS module, such as EHS module 304, an energy storing circuit, such as energy storing circuit 306, and/or a battery, such as battery 308. In some embodiments, the piezoelectric energy harvester 100 of FIG. 1 is suitable as the energy generating element. The EHS module may be electrically coupled to the energy generating element, the energy storing circuit, and/or the battery. In some embodiments, the energy generating element may include a dielectric generating material, a piezoelectric generating material, or other material, system, or device that generates electricity when subject to motion, mechanical stress, or other input, or a combination thereof. In some embodiments, the energy generating element may be the piezoelectric energy harvester described herein. In some embodiments, flexing of the energy generating element, e.g., implemented as a piezoelectric energy harvester described herein, and/or portions of a detector patch that has such materials may generate a charge on the surface of the energy generating element. In some embodiments, the energy generating element may be disposed in close proximity to a tread portion, a shoulder portion, and/or a sidewall portion of a tire.

In some embodiments, a method for preparing a piezoelectric composite energy harvester may comprise providing a silicone oligomer that after curing has a hardness of about 5 to about 90 shore A; providing a mixture comprising the silicone oligomer and piezoelectric particles dispersed within the silicone oligomer; casting the mixture to form a composite sheet; curing the composite sheet; polarizing the piezoelectric particles within the composite sheet; producing a first electrode from a conductive material, wherein the step of producing the first electrode comprises forming the conductive material onto a first side of the composite sheet; producing a second electrode from a conductive material, wherein the step of producing the second electrode comprises forming the conductive material onto a second side of the composite sheet; and producing an elastic cover layer from silicone, wherein the step of producing the elastic cover layer comprises forming the silicone onto the first or second electrode.

In some embodiments, the step of producing the first electrode and second electrode may comprise forming the conductive material by a printing method, a casting method, and/or a coating method. In some embodiments, the printing method may comprise screen printing. In some embodiments, the step of producing the elastic cover layer may comprise forming the conductive material by a printing method, a casting method, and/or a coating method. In some embodiments, the printing method may comprise screen printing.

In some embodiments, the step of producing an elastic cover layer from silicone may further comprise mixing the silicone with a solvent. In some embodiments, the solvent may comprise toluene.

Hereinafter, embodiments and methods will be described in more detail.

### EMBODIMENTS

Embodiment 1. A piezoelectric composite energy harvester comprising:
a piezoelectric element comprising a first electrode, a second electrode, and a piezoelectric layer comprising a cross-linked silicone elastomer matrix and piezoelectric particles, wherein the piezoelectric particles are dispersed within the cross-linked silicone elastomer matrix, wherein the first electrode is disposed on a first side of the piezoelectric layer, wherein the second electrode is disposed on a second side of the piezoelectric layer, and
an elastic cover layer contiguous with the second electrode, wherein the elastic cover layer is arranged so as to cover an outer side of the second electrode, wherein the elastic modulus of the elastic cover layer is less than the elastic modulus of the piezoelectric element,
wherein the piezoelectric composite energy harvester is configured to bend, expand, contract, rotate, tilt, and/or move in all spatial directions.
Embodiment 2. The piezoelectric composite energy harvester of embodiment 1, wherein the thickness ratio of the elastic cover layer to the piezoelectric element is about 0.01 or more.
Embodiment 3. The piezoelectric composite energy harvester of embodiment 1, wherein the thickness ratio of the elastic cover layer to the piezoelectric element is greater than about 0.01 and less than about 2.
Embodiment 4. The piezoelectric composite energy harvester of embodiment 1, wherein the piezoelectric composite energy harvester has a tensile stress at 20% elongation of about 1.5 to about 4 MPa.
Embodiment 5. The piezoelectric composite energy harvester of embodiment 1, wherein the piezoelectric composite energy harvester has a tensile stress at 35% elongation of about 1.5 to about 4 MPa.
Embodiment 6. The piezoelectric composite energy harvester of embodiment 1, wherein the piezoelectric composite energy harvester has a tensile stress at 40% elongation of about 1.5 to about 4 MPa.
Embodiment 7. The piezoelectric composite energy harvester of embodiment 1, wherein the piezoelectric composite energy harvester has a tensile stress at 45% elongation of about 2 to about 4.5 MPa.
Embodiment 8. The piezoelectric composite energy harvester of embodiment 1, wherein the piezoelectric composite energy harvester has a tensile stress at 50% elongation of about 2 to about 4.5 MPa.
Embodiment 9. The piezoelectric composite energy harvester of embodiment 1, wherein the piezoelectric layer has a thickness between about 5 μm to about 500 μm.
Embodiment 10. The piezoelectric composite energy harvester of embodiment 1, wherein the elastic cover layer comprises silicone.
Embodiment 11. The piezoelectric composite energy harvester of embodiment 1, wherein the first and second electrode comprise a conductive material and a silicone.
Embodiment 12. The piezoelectric composite energy harvester of embodiment 11, wherein the conductive material comprises a conductive particle, wherein the conductive particle comprises carbon black, nickel nano strands, silver nanoparticles, graphene nanoplatelets, and/or graphene-oxide.
Embodiment 13. A tire equipped with a piezoelectric composite energy harvester of embodiments 1-12.
Embodiment 14. A method for preparing a piezoelectric composite energy harvester of embodiments 1-12 comprising:
providing a silicone oligomer that after curing has a hardness of about 5 to about 90 shore A;
providing a mixture comprising the silicone oligomer and piezoelectric particles, the piezoelectric particles dispersed within the silicone oligomer;
casting the mixture to form a composite sheet;
curing the composite sheet;
polarizing the piezoelectric particles within the composite sheet;
producing a first electrode from a conductive material, wherein the step of producing the first electrode comprises forming the conductive material onto a first side of the composite sheet;
producing a second electrode from a conductive material, wherein the step of producing the second electrode comprises forming the conductive material onto a second side of the composite sheet; and
producing an elastic cover layer from silicone, wherein the step of producing the elastic cover layer comprises forming the silicone onto the first or second electrode.
Embodiment 15. The method of embodiment 14, wherein the step of producing the first electrode and second electrode comprises forming the conductive material by a printing method, a casting method, and/or a coating method.
Embodiment 16. The method of embodiment 15, wherein the printing method comprises screen printing.
Embodiment 17. The method of embodiment 14, wherein the step of producing the elastic cover layer comprises forming the conductive material by a printing method, a casting method, and/or a coating method.
Embodiment 18. The method of embodiment 17, wherein the printing method comprises screen printing.

### EXAMPLES

It should be appreciated that the following Examples are for illustration purposes and are not intended to be construed as limiting the subject matter disclosed in this document to only the embodiments disclosed in these examples.

### Preparing Composites

### Example 1

An electrode ink, which was a uniform mixture of 60.5 g of polydimethylsiloxane (PDMS), made as described in Sci Rep 9, 1 (2019), 6.3 g of carbon black and 131.7 g of toluene, was coated on a fluorinated polymer substrate, followed by heat-treatment in an oven at 80° C. for 15 minutes and then at 200° C. for 15 minutes to make a thin layer of elastic electrode.

14 g of piezoelectric (PZT) particles was mixed with 2 g of polydimethylsiloxane (PDMS) (Shore A Hardness 80, reactive unit at 9.4 mol %), and 2.8 g of toluene in a planetary centrifugal mixer for 4 min. A uniform slurry was obtained. The slurry was cast at a wet thickness of 24 mil on top of the layer of elastic electrode using a film applicator. The cast film then was heated in an oven at 80° C. for 15 minutes to remove the solvent and then at 200° C. for 30 minutes to complete the cross-linking reaction. A composite film was obtained.

The same electrode ink was coated on top of the composite film, followed by heat-treatment in an oven at 80° C. for 15 minutes and then at 200° C. for 15 minutes to make a second thin layer of elastic electrode. A 3-layer composite structure was obtained.

The composite structure was then sandwiched between two copper plates on a hotplate set at 130° C. A voltage of 6.0 kV was applied on one of the copper plates, creating an electric field across the composite structure to polarize the PZT particles dispersed within for 60 min. A poled composite sample was obtained.

### Example 2

Example 2 was made in a similar manner to Example 1, except with the addition of an elastic cover layer. An elastic cover layer ink, which was a uniform mixture of 4 g of polydimethylsiloxane (PMDS) (Shore A Hardness 80, reactive unit at 9.4 mol %) and 0.4 g of toluene, was coated on top of poled composite structure, followed by heat-treatment in an oven at 80° C. for 15 minutes and then at 150° C. for 20 minutes to make an elastic cover layer.

### Measurement of Stress at 1% Elongation

A 1×3 cm² specimen was cut from a composite sample. The average thickness of 1×1 cm² at the center of the specimen was measured. The specimen was clamped on an AGS-X tensile tester (Shimadzu, Japan) to have that 1×1 cm² at center stretched at a stroke rate of 5 mm/min. The stress value at 1% elongation (0.1 mm) was recorded.

### Measurement of Power Generation

Composite sample was fixed on an ACT165DL linear actuator (Aerotech, Pittsburgh, PA). Its elastic electrodes were connected to an oscilloscope with a load resistor R of 1 MΩ. The sample was subject to 3% tensile deformation at a frequency of 20 Hz. The generated power was calculated by

$${V}_{r m s}^{2} / R .$$

### Conformity of Sample

A 10×10 cm² sample was laminated on a patch on the inner liner of tire which was abraded beforehand to make the surface smooth. The conformity of the sample was considered good if there were no wrinkles, no lift-off, or no cracks. On the other hand, the conformity was considered poor if there were wrinkles, partial lift-off, or cracks.

### Results

TABLE 1

| | Shore | | | | poling | | power |
|---|---|---|---|---|---|---|---|
| | A | Vol | mol % | tensile | field | | (3% |
| | (CL | % | reactive | stress | (kV/ | Con- | tensile |
| | ELM) | piezo | unit | @1% | mm) | formity | deform.)* |
| Example | 80 | 50 | 9.4 | 1.6 | 20 | Good | Excellent |
| 1 (w/o | | | | | | | |
| elastic | | | | | | | |
| cover | | | | | | | |
| layer) | | | | | | | |
| Example | 80 | 50 | 9.4 | 0.47 | 20 | Good | Excellent |
| 2 (w/ | | | | | | | |
| elastic | | | | | | | |
| cover | | | | | | | |
| layer) | | | | | | | |

*power@3% tensile deformation
excellent: ≥5 uW/cm2
good: ≥0.5 uW/cm2
poor: <0.5 uW/cm2

The results in Table 1 above illustrate the benefits the currently disclosed improved piezoelectric harvester may provide, both desired levels of conformity and power generation at 3% tensile deformation, when a piezoelectric generator was constructed as described herein.

Use of the term “may” or “may be” should be construed as shorthand for “is” or “is not” or, alternatively, “does” or “does not” or “will” or “will not,” etc. For example, the statement “a thermally conductive composite may further comprise a backing layer” should be interpreted as, for example, “In some embodiments, a thermally conductive composite further comprises a backing layer,” or “In some embodiments, a thermally conductive composite does not further comprise a backing layer.”

Unless otherwise indicated, all numbers expressing quantities of ingredients, properties, such as, molecular weight, reaction conditions, and so forth used in the specification and embodiments are to be understood as being modified in all instances by the term “about.” The term “about” as used herein, may include any numerical value that may vary without changing the basic function of that value. When used with a range, “about” also discloses the range defined by the absolute values of the two endpoints. The term “about” may refer to plus or minus 10% of the indicated number.

Accordingly, unless indicated to the contrary, the numerical parameters set forth in the specification and attached embodiments are approximations that may vary depending upon the desired properties sought to be obtained. At the very least, and not as an attempt to limit the application of the doctrine of equivalents. To the scope of the embodiments, each numerical parameter should at least be construed in light of the number of reported significant digits and by applying ordinary rounding techniques.

For the processes and/or methods disclosed, the functions performed in the processes and methods may be implemented in differing order, as may be indicated by context. Furthermore, the outlined steps and operations are only provided as examples, and some of the steps and operations may be optional, combined into fewer steps and operations, or expanded into additional steps and operations.

This disclosure may sometimes illustrate different components contained within, or connected with, different other components. Such depicted architectures are merely examples, and many other architectures may be implemented which achieve the same or similar functionality.

The terms used in this disclosure, and in the appended embodiments, are generally intended as “open” terms (e.g., the term “including” should be interpreted as “including, but not limited to,” the term “having” should be interpreted as “having at least,” the term “includes” should be interpreted as “includes, but is not limited to,” etc.). In addition, if a specific number of elements is introduced, this may be interpreted to include at least the recited number, as may be indicated by context (e.g., the bare recitation of “two recitations,” without other modifiers, includes at least two recitations, or two or more recitations). As used in this disclosure, any disjunctive word and/or phrase presenting two or more alternative terms should be understood to contemplate the possibilities of including one of the terms, either of the terms, or both terms. For example, the phrase “A or B” will be understood to include the possibilities of “A” or “B” or “A and B.”

The terms and words used are not limited to the bibliographical meanings but are merely used to enable a clear and consistent understanding of the disclosure. The terms “a,” “an,” “the” and similar referents used in the context of describing the present disclosure (especially in the context of the following embodiments) are to be construed to cover both the singular and the plural, unless otherwise indicated herein or clearly contradicted by context. The use of any and all examples, or representative language (e.g., “such as”) provided herein is intended merely to better illuminate the present disclosure and does not pose a limitation on the scope of any embodiments. No language in the specification should be construed as indicating any non-embodied element essential to the practice of the present disclosure.

Groupings of alternative elements or embodiments disclosed herein are not to be construed as limitations. Each group member may be referred to and embodied individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended embodiments.

Certain embodiments are described herein, including the best mode known to the inventors for carrying out the present disclosure. Of course, variations on these described embodiments, will become apparent to those of ordinary skill in the art upon reading the foregoing description. The inventor expects skilled artisans to employ such variations as appropriate, and the inventors intend for the present disclosure to be practiced otherwise than specifically described herein. Accordingly, the embodiments include all modifications and equivalents of the subject matter recited in the embodiments as permitted by applicable law. Moreover, any combination of the above-described elements in all possible variations thereof is contemplated unless otherwise indicated herein or otherwise clearly contradicted by context. In closing, it is to be understood that the embodiments disclosed herein are illustrative of the principles of the embodiments. Other modifications that may be employed are within the scope of the embodiments. Thus, by way of example, but not of limitation, alternative embodiments may be utilized in accordance with the teachings herein. Accordingly, the embodiments are not limited to the embodiments precisely as shown and described.

By the term “substantially” it is meant that the recited characteristic, parameter, or value need not be achieved exactly, but that deviations or variations, including for example, tolerances, measurement error, measurement accuracy limitations and other factors known to those skilled in the art, may occur in amounts that do not preclude the effect the characteristic was intended to provide.

Aspects of the present disclosure may be embodied in other forms without departing from its spirit or essential characteristics. The described aspects are to be considered in all respects illustrative and not restrictive. The embodied subject matter is indicated by the appended embodiments rather than by the foregoing description. All changes, which come within the meaning and range of equivalency of the embodiments, are to be embraced within their scope.

1. A piezoelectric composite energy harvester comprising:
a piezoelectric element comprising piezoelectric layer disposed between a first electrode and a second electrode, wherein the piezoelectric layer comprises piezoelectric particles dispersed within a cross-linked silicone elastomer matrix; and
an elastic cover layer contiguous with the second electrode, wherein the elastic cover layer is arranged so as to cover an outer side of the second electrode, wherein the elastic modulus of the elastic cover layer is less than the elastic modulus of the piezoelectric element,
wherein the piezoelectric composite energy harvester is configured to bend, expand, contract, rotate, tilt, or move in all spatial directions.

2. The piezoelectric composite energy harvester of claim 1, wherein the thickness ratio of the elastic cover layer to the piezoelectric element is about 0.01 or more.

3. The piezoelectric composite energy harvester of claim 1, wherein the thickness ratio of the elastic cover layer to the piezoelectric element is greater than about 0.01 and less than about 2.

4. The piezoelectric composite energy harvester of claim 1, wherein the piezoelectric composite energy harvester has a tensile stress at 20% elongation of about 1.5 to about 4 MPa.

5. The piezoelectric composite energy harvester of claim 1, wherein the piezoelectric composite energy harvester has a tensile stress at 35% elongation of about 1.5 to about 4 MPa.

6. The piezoelectric composite energy harvester of claim 1, wherein the piezoelectric composite energy harvester has a tensile stress at 40% elongation of about 1.5 to about 4 MPa.

7. The piezoelectric composite energy harvester of claim 1, wherein the piezoelectric composite energy harvester has a tensile stress at 45% elongation of about 2 to about 4.5 MPa.

8. The piezoelectric composite energy harvester of claim 1, wherein the piezoelectric composite energy harvester has a tensile stress at 50% elongation of about 2 to about 4.5 MPa.

9. The piezoelectric composite energy harvester of claim 1, wherein the piezoelectric layer has a thickness between about 5 μm to about 500 μm.

10. The piezoelectric composite energy harvester of claim 1, wherein the elastic cover layer comprises silicone.

11. The piezoelectric composite energy harvester of claim 1, wherein the first and second electrode comprise a conductive material and a silicone.

12. The piezoelectric composite energy harvester of claim 11, wherein the conductive material comprises a conductive particle comprising carbon black, nickel nano strands, silver nanoparticles, graphene nanoplatelets, graphene-oxide, or a combination thereof.

13. A capacitive tire sensor comprising:
a sensor module, the sensor module comprising an electric power source.

14. The capacitive tire sensor of claim 13, wherein the electric power source comprises a piezoelectric composite energy harvester.

15. The capacitive tire sensor of claim 13, wherein the capacitive tire sensor further comprises an energy generating circuit electrically coupled to the electric power source, wherein the energy generating circuit comprises a piezoelectric composite energy harvester.

16. A method for preparing a piezoelectric composite energy harvester of claim 1, comprising:
mixing piezoelectric particles mixture into a silicone oligomer so that the piezoelectric particles are dispersed within the silicone oligomer;
casting the mixture to form a composite sheet;
curing the composite sheet, wherein the silicone oligomer has a hardness of about 5 to about 90 Shore A after curing;
polarizing the piezoelectric particles within the composite sheet;
producing a first electrode from a conductive material, wherein the step of producing the first electrode comprises forming the conductive material onto a first side of the composite sheet;
producing a second electrode from a conductive material, wherein the step of producing the second electrode comprises forming the conductive material onto a second side of the composite sheet; and
producing an elastic cover layer from silicone, wherein the step of producing the elastic cover layer comprises forming the silicone onto the first electrode or the second electrode.

17. The method of claim 16, wherein the step of producing the first electrode and the second electrode comprises forming the conductive material by a printing method, a casting method, a coating method, or a combination thereof.

18. The method of claim 17, wherein the printing method comprises screen printing.

19. The method of claim 16, wherein the step of producing the elastic cover layer comprises forming the conductive material by a printing method, a casting method, a coating method, or a combination thereof.

20. The method of claim 19, wherein the printing method comprises screen printing.
